(19) United States
(12) Patent Application Publication
(10) Pub. No.: US 2025/0139334 A1
(43) Pub. Date: May 1, 2025

(54) MODIFYING WIRELESS NETWORK CAPACITY BASED ON PLANNED STRUCTURAL CHANGES

(71) Applicant: Charter Communications Operating, LLC, St. Louis, MO (US)

(72) Inventor: Michael Bender, Rye Brook, NY (US)

(21) Appl. No.: 18/498,603

(22) Filed: Oct. 31, 2023

(51) Int. Cl. G06F 30/27

(52) U.S. Cl. CPC G06F 30/27

(57) ABSTRACT

A computing system generates a digital twin of a physical environment comprising a virtual representation of a physical structure in the physical environment. The computing system obtains planned construction data representative of a planned change to the physical environment. The computing system modifies the digital twin based on the planned construction data to generate a modified digital twin. The computing system determines, based on the modified digital twin, an impact to a radiation pattern of a transceiver located in the physical environment that is caused by the planned change to the physical environment.

### BACKGROUND

Wireless networks, such as cellular networks (e.g., Fourth Generation (4G) networks, Fifth Generation (5G) networks, etc.) and/or Wi-Fi® networks, are operated by network service providers and are operable to provide wireless connectivity to a wide variety of computing devices, such as smartphones, tablets, Internet of Things (IoT) devices, and the like. To do this, network service providers deploy, operate, maintain, etc. a wide array of network infrastructure hardware, including transceivers (e.g., cellular base stations, Wi-Fi® transceivers, distributed antenna systems (DAS), femtocell and picocell transceivers, machine-to-machine (M2M)/Internet-of-Things (IoT) transceivers, etc.).

### SUMMARY

The examples disclosed herein modify wireless network capacity based on planned structural changes in a physical environment.

In one implementation, a method is provided. The method includes generating, by a computing system, a digital twin of a physical environment, the digital twin comprising a virtual representation of a physical structure in the physical environment. The method further includes obtaining, by the computing system, planned construction data representative of a planned change to the physical environment. The method further includes modifying, by the computing system, the digital twin based on the planned construction data to generate a modified digital twin. The method further includes determining, by the computing system based on the modified digital twin, an impact to a radiation pattern of a transceiver located in the physical environment by the planned change to the physical environment.

In another implementation, a computing system is provided. The computing system includes one or more computing devices operable to generate a digital twin of a physical environment, the digital twin comprising a virtual representation of a physical structure in the physical environment. The one or more computing devices are further operable to obtain planned construction data representative of a planned change to the physical environment. The one or more computing devices are further operable to modify the digital twin based on the planned construction data to generate a modified digital twin. The one or more computing devices are further operable to determine, based on the modified digital twin, an impact to a radiation pattern of a transceiver located in the physical environment by the planned change to the physical environment.

In another implementation, a non-transitory computer-readable storage medium is provided. The non-transitory computer-readable storage medium includes executable instructions configured to cause one or more processor devices to generate a digital twin of a physical environment, the digital twin comprising a virtual representation of a physical structure in the physical environment. The executable instructions are further configured to cause the one or more processor devices to obtain planned construction data representative of a planned change to the physical environment. The executable instructions are further configured to cause the one or more processor devices to modify the digital twin based on the planned construction data to generate a modified digital twin. The executable instructions are further configured to cause the one or more processor devices to determine, based on the modified digital twin, an impact to a radiation pattern of a transceiver located in the physical environment by the planned change to the physical environment.

Individuals will appreciate the scope of the disclosure and realize additional aspects thereof after reading the following detailed description of the examples in association with the accompanying drawing figures.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1 is a block diagram of an environment suitable for modifying network capacity based on planned structural changes according to one implementation;

FIG. 2 is a flowchart of a method for determining a network impact according to one implementation;

FIG. 3 is a flowchart of a method for determining an impact to a transceiver according to one implementation;

FIG. 4 is a flowchart of a method for predicting a network impact according to one implementation;

FIG. 5 is a flowchart of a method for determining a network configuration according to one implementation;

FIG. 6 is a diagram illustrating network capacity modifications based on planned structural changes according to one implementation; and

FIG. 7 is a block diagram of the computing system suitable for implementing examples disclosed herein.

### DETAILED DESCRIPTION

The examples set forth below represent the information to enable individuals to practice the examples and illustrate the best mode of practicing the examples. Upon reading the following description in light of the accompanying drawing figures, individuals will understand the concepts of the disclosure and will recognize applications of these concepts not particularly addressed herein. It should be understood that these concepts and applications fall within the scope of the disclosure and the accompanying claims.

Any flowcharts discussed herein are necessarily discussed in some sequence for purposes of illustration, but unless otherwise explicitly indicated, the examples are not limited to any particular sequence of steps. The use herein of ordinals in conjunction with an element is solely for distinguishing what might otherwise be similar or identical labels, such as “first message” and “second message,” and does not imply an initial occurrence, a quantity, a priority, a type, an importance, or other attribute, unless otherwise stated herein. The term “about” used herein in conjunction with a numeric value means any value that is within a range of ten percent greater than or ten percent less than the numeric value. As used herein and in the claims, the articles “a” and “an” in reference to an element refers to “one or more” of the element unless otherwise explicitly specified. The word “or” as used herein and in the claims is inclusive unless contextually impossible. As an example, the recitation of A or B means A, or B, or both A and B. The word “data” may be used herein in the singular or plural depending on the context. The use of “and/or” between a phrase A and a phrase B, such as “A and/or B” means A alone, B alone, or A and B together.

Wireless networks, such as cellular networks (e.g., Fourth Generation (4G) networks, Fifth Generation (5G) networks, etc.) and/or Wi-Fi® networks, may be operated by network service providers and are operable to provide wireless connectivity to a wide variety of computing devices, such as smartphones, tablets, Internet of Things (IoT) devices, and the like. To do this, network service providers deploy, operate, maintain, etc. a wide array of network infrastructure hardware, including transceivers (e.g., cellular base stations, Wi-Fi® transceivers, distributed antenna systems (DAS), femtocell and picocell transceivers, machine-to-machine (M2M)/Internet-of-Things (IoT) transceivers, etc.).

As discussed herein, wireless network transceivers are operable to transmit signals by converting digital data from the wireless network into electromagnetic signals suitable for wireless transmission to a downstream device, such as intermediate network devices in the wireless network (e.g., cable modem, switching device, etc.) and/or internet-enabled user devices (e.g., smartphone, tablet device, mobile computing device, etc.). Wireless network transceivers are further operable to receive signals from the aforementioned intermediate network devices in the wireless network and/or the internet-enabled user devices by capturing incoming electromagnetic signals originating from those devices. In some implementations, wireless network transceivers are operable to transmit and receive data simultaneously (via, e.g., full-duplex communication) by allowing a transmitter and a receiver of the wireless network transceiver to operate independently at the same time. It should be understood that any suitable transceiver may be used without deviating from the scope of the present disclosure.

To provide wireless connectivity to user devices, transceivers of the wireless network must be able to transmit signals to, and receive signals from, the various devices on the wireless network (e.g., internet-enabled user devices, intermediate network devices, etc.) (hereinafter “end device(s)”). In addition to the network infrastructure deployed by network service providers, a physical environment in which the end device is located greatly affects whether (and to what degree) the end device can enjoy the wireless connectivity provided via the wireless network. As one example, end devices that are closer to the nearest transceiver may enjoy better connectivity than end devices located farther away from the transceiver. Additionally, physical obstructions and structures in the physical environment, such as buildings, walls, trees, etc., may also weaken signals transmitted to and from a transceiver.

Construction changes in the physical environment (e.g., new physical structure(s), modifications of existing physical structure(s), removal of existing physical structure(s), etc.) often impact the ability for the end device to utilize the wireless network (via the transceiver(s)) without a degradation of service caused by the changes to the physical environment. By way of non-limiting example, suppose the physical environment corresponds to a city block and further suppose a new structure is built between an existing structure and the nearest transceiver. Due to this new structure in the physical environment, the wireless connectivity of devices located in the existing structure may be adversely affected due to the resulting signal obstructions caused by the new structure. As such, a network service provider may desire to determine connectivity-related impacts to wireless networks based on planned changes to the physical environment in order to selectively deploy and/or modify wireless network capacity prior to the planned changes taking place.

The examples disclosed herein implement a “digital twin” (e.g., virtual representation) of a physical environment to determine connectivity-related impacts to wireless networks based on the planned changes to the physical environment. As discussed in greater detail below, the present disclosure provides a computing system that is operable to generate and modify a digital twin of a physical environment, based on past, present, and future construction data associated with the physical environment, to determine one or more network impacts resulting from planned changes to the physical environment. Additionally, the computing system is further operable to proactively determine and recommend modifications to the network capacity in the physical environment to preempt the determined network impacts.

More particularly, the computing system may include one or more machine-learned models operable to ingest environment data associated with a particular physical environment. Furthermore, based on the environment data, the computing system may generate a digital twin of the particular physical environment. By way of non-limiting example, in some implementations, the computing system may generate the digital twin based on one or more images depicting a plurality of physical structures in the physical environment. Additionally and/or alternatively, in some implementations, the computing system may generate the digital twin based on construction data (e.g., blueprints, building permits, construction materials, etc.) identifying the plurality of physical structures in the physical environment.

Furthermore, the computing system may modify the digital twin based on planned construction data identifying various planned changes to the physical environment. For example, the planned construction data may identify a new structure that is to be added to the physical environment, and the computing system may generate a modified digital twin having the new structure added thereto. Additionally and/or alternatively, the planned construction data may identify an existing structure that is to be modified or removed from the physical environment, and the computing system may generate a modified digital twin having the modified structure or the existing structure removed therefrom.

After generating and modifying the digital twin, the computing system may perform (via, e.g., one or more machine-learned models) a variety of simulations to determine whether the planned structural changes will impact the network servicing the physical environment. The simulations may utilize historical data used in a training model to determine the impact. Historical data, in a non-limiting example, may be metrics from a receiving device that measures the quality of received signals (e.g., a phone knows how many “bars” of signal strength it has). By way of another non-limiting example, the historical data may be based on historical complaints received from users following a deployment of changes to the physical environment that were determined to have caused a degradation in service. Furthermore, the computing system may also perform a variety of simulations to determine possible mitigative actions that may be taken to avoid the predicted impacts to the network.

Implementations of the present disclosure provide a number of technical effects and benefits. As one example technical effect and benefit, a quality of service provided by the wireless network can be maintained and improved, regardless of how (and to what degree) the physical environment serviced by the wireless network changes, by utilizing a digital twin to determine the network-related impacts and mitigative measures. In this manner, the present disclosure obviates the inefficiencies and delays associated with ex post impact and mitigation determinations, while, simultaneously, maximizing the quality of the service provided by the wireless network. For instance, the present disclosure maximizes the quality of the service provided by the wireless network by reducing coverage gaps caused by the planned changes for devices that subscribe to wireless network services.

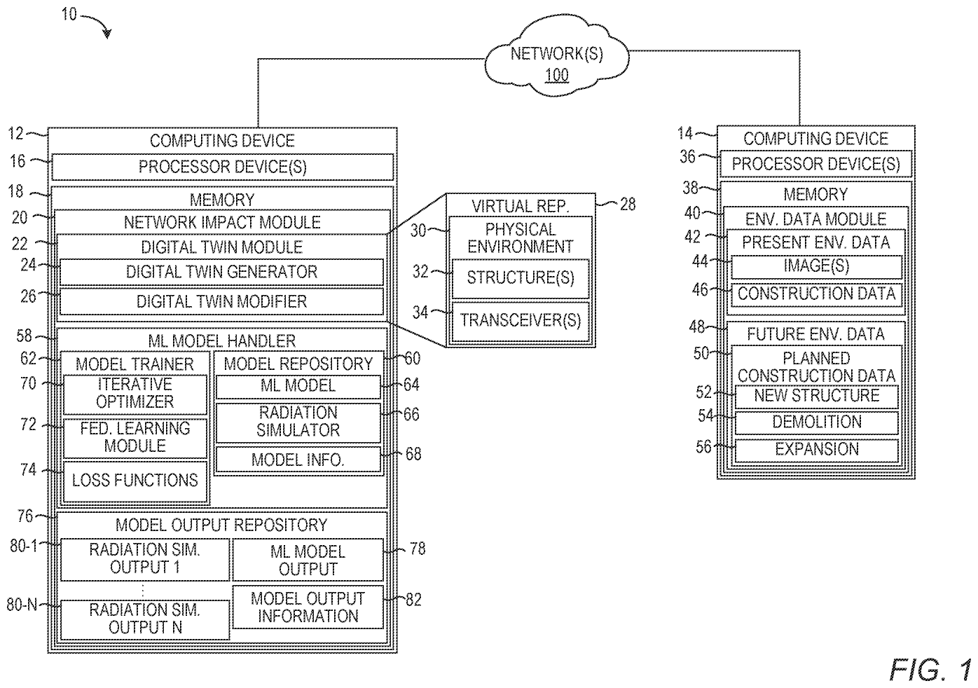

FIG. 1 is a block diagram of an environment suitable for implementing network capacity modifications based on planned structural changes according to one implementation of the present disclosure. The environment includes a computing system 10. In some implementations, such as that depicted in FIG. 1, the computing system 10 may be a computing system that includes multiple computing devices, such as a computing device 12 and a computing device 14. Alternatively, in some implementations, the computing system 10 may be one or more computing devices (e.g., computing device 12) within a computing environment that includes multiple distributed devices and/or systems. It should be understood that the computing system 10 is depicted with two computing devices (i.e., computing device 12, computing device 14) for purposes of illustration and discussion.

As shown, the computing device 12 includes processor device(s) 16 and a memory 18. The processor device(s) 16 may include any computing or electronic device capable of executing software instructions to implement the functionality described herein. The memory 18 can be or otherwise include any device(s) capable of storing data, including, but not limited to, volatile memory (random access memory, etc.), non-volatile memory, storage device(s) (e.g., hard drive(s), solid state drive(s), etc.).

In particular, as shown, the memory 18 can include a network impact module 20. The network impact module 20 can be, or otherwise include, any manner or collection of hardware (e.g., physical or virtualized) and/or software resources sufficient to implement the various implementations described herein. As discussed below, the network impact module 20 may be operable to determine one or more network impacts resulting from changes to the physical environment services by a wireless network. The network impact module 20 may further determine and recommend one or more mitigative actions, such as additions or modifications to network capacity in the physical environment, to preempt the determined network impacts.

In particular, the network impact module 20 may include a digital twin module 22. The digital twin module 22 may include a digital twin generator 24 and a digital twin modifier 26. As discussed herein, the digital twin module 22 may be utilized to generate, optimize, render, modify, etc. a three-dimensional (3D) virtual representation (e.g., a “digital twin”) of a physical environment.

To do so, the digital twin generator 24 may generate a digital twin 28 which, as noted above, is a virtual representation of a physical environment 30. As will be discussed in greater detail below, the physical environment 30 may include one or more physical structure(s) 32 and one or more transceiver(s) 34 having a corresponding radiation pattern. Hence, the digital twin 28 may include a virtual representation of the one or more physical structure(s) 32. In some implementations, the digital twin 28 may also include a virtual representation of the one or more transceiver(s) 34. Alternatively, in other implementations, the digital twin 28 may include data indicative of a corresponding location of the one or more transceiver(s) 34 (respectively) in the physical environment 30.

As noted above, the transceiver(s) 34 is operable to transmit and receive data signals between devices utilizing a wireless network, thereby operating as a network interface for a variety of devices, such as the end devices discussed above. It should be understood that the transceiver(s) 34 may be any suitable device operable to transmit and receive data signals on any suitable wireless network. By way of non-limiting example, the transceiver(s) 34 may be cellular base stations, Wi-Fi® transceivers, Bluetooth® transceivers, and the like. In this manner, the transceiver(s) 34 may service any suitable wireless network, such as a Fifth Generation (5G) NR wireless network, a Fourth Generation (4G) Long-Term Evolution (LTE) network, a high-speed Wi-Fi network, a high-speed residential network, and the like.

Furthermore, as will be discussed in greater detail below, the transceiver(s) 34 includes a radiation pattern corresponding to how the transceiver(s) 34 radiates (i.e., transmits) and/or receives electromagnetic signals. More particularly, radiation patterns depict the directions from which the transceiver(s) 34 transmit and receive signals from various devices on the wireless network. It should be understood that transceiver(s) 34 may have any suitable radiation pattern. By way of non-limiting example, the radiation pattern associated with the transceiver(s) 34 may be isotropic, omnidirectional, directional, beamwidth, etc. The coverage area, overall performance, and various other operating characteristics of the transceiver(s) 34 (e.g., gain, directivity) depend, in large part, on the particular radiation pattern associated with the transceiver(s) 34. Thus, any impacts to the radiation pattern associated with the transceiver(s) 34 may negatively affect the wireless connectivity enjoyed by the end device serviced by the transceiver(s) 34.

A “physical environment,” as described herein, generally refers to a demarcated space in which network infrastructure is deployed. It should be understood that the physical environment 30 may be any suitable size without deviating from the scope of the present disclosure. For instance, in some implementations, the physical environment 30 may be a studio apartment. Alternatively, in some implementations, the physical environment 30 may be a single-family house. Even further, in some implementations, the physical environment 30 may be a residential neighborhood or one or more city blocks in a densely populated urban center.

To generate the digital twin 28, the digital twin module 22 accesses and receives environment data associated with the physical environment 30 from a computing device of the computing system 10, such as computing device 14. For instance, in some implementations, the computing device 14 may transmit the environment data to the computing device 12 via a network connection implemented by a network(s) 100. The network(s) 100 can be one or more wired and/or wireless networks capable of conveying information between devices of the computing system 10, such as the computing device 12 and the computing device 14. By way of non-limiting example, the network(s) 100 may be, e.g., a 5G NR wireless network, a Fourth Generation (4G) Long-Term Evolution (LTE) network, a high-speed Wi-Fi network, a high-speed residential network such as a fiber-optic or cable network, etc.

The computing device 14 may be communicatively coupled to computing device 12 and can include processor device(s) 36 and memory 38 as described with regards to the processor device(s) 16 and memory 18 of the computing device 12. The computing device 14 can be any type or manner of device that can obtain environment data and transmit environment data to the computing device 12 (e.g., a smartphone, laptop, tablet, desktop computing device, wearable computing device, peripheral computing device (e.g., Augmented Reality (AR)/Virtual Reality (VR) device, wireless earbuds device, etc.), etc.).

More particularly, the memory 38 may include an environment data module 40 comprising data corresponding to a plurality of physical environments, such as the physical environment 30. In some implementations, the environment data module 40 may include data 42 corresponding to a current state of the physical environment 30 (hereinafter “present environment data 42”), such as one or more images 44 depicting the physical environment 30 and construction data 46 corresponding to previous construction projects undertaken in the physical environment 30.

For instance, in some implementations, the one or more images 44 may depict the physical structure(s) 32 in the physical environment 30. Furthermore, the construction data 46 may identify a plurality of structures, including the physical structure(s) 32, in the physical environment 30. By way of non-limiting example, the construction data 46 may include a blueprint that identifies the physical structure(s) 32, data identifying building materials (e.g., external construction material) of the physical structure(s) 32, location(s) of one or more transceivers (e.g., transceiver(s) 34) in the physical environment 30, etc.

To generate the digital twin 28, the digital twin module 22 (e.g., the digital twin generator 24) accesses and receives the present environment data 42 and generates the digital twin 28 based on the present environment data 42. In some implementations, the digital twin module 22 may access the one or more images 44 depicting the physical structure(s) 32 in the physical environment 30, and the digital twin generator 24 may generate the digital twin 28 based on the one or more images 44. Additionally and/or alternatively, in some implementations, the digital twin module 22 may access the construction data 46 identifying a plurality of physical structures (e.g., physical structure(s) 32) in the physical environment 30, and the digital twin generator 24 may generate the digital twin 28 based on the construction data 46.

The environment data module 40 may also include data 48 corresponding to a future (e.g., planned) state of the physical environment 30 (hereinafter “future environment data 48”), such as planned construction data 50 that is representative of a planned change to the physical environment 30. By way of non-limiting example, in some implementations, the planned construction data 50 may be a document (e.g., data file) that identifies one or more physical attributes of the planned change to the physical environment 30 that may be obtained from, e.g., a local building department.

As noted above, the digital twin module 22 may be utilized to modify the digital twin 28. In particular, to modify the digital twin 28, the digital twin module 22 (e.g., the digital twin modifier 26) obtains the future environment data 48 and, subsequently, may modify the digital twin 28 based on the future environment data 48.

The future environment data 48 may include planned construction data 50. More particularly, in some implementations, the planned construction data 50 may include data 52 identifying a new structure that is to be added to the physical environment 30. In such implementations, the digital twin module 22 can modify the digital twin 28 to include a virtual representation of the new structure based on the data 52.

In some implementations, the planned construction data 50 may include data 54 identifying an existing physical structure that is to be removed from the physical environment 30. In such implementations, the digital twin module 22 can modify the digital twin 28 to remove the virtual representation of the existing physical structure based on the data 54.

In some implementations, the planned construction data 50 may include data 56 identifying an expansion to an existing physical structure in the physical environment 30. In such implementations, the digital twin module 22 can modify the digital twin 28 to modify the virtual representation of the existing physical structure based on the data 56.

The network impact module 20 may further include a machine-learned model handler 58. The machine-learned model handler 58 can obtain, instantiate, train, optimize, and utilize various machine-learned models. To do so, the machine-learned model handler 58 can include a model repository 60 and a model trainer 62. The model repository 60 can store and catalogue information regarding each of the machine-learned models utilized to modify the digital twin 28, to determine network impacts caused by planned changes to the physical environment 30, to determine modifications to wireless network capacity based on the impacts caused by the planned changes to the physical environment 30, etc. The model trainer 62 can be utilized to train the models stored in the model repository 60.

The model repository 60 can store one or more machine-learned models, such as machine learning model 64 and radiation simulator 66, that are utilized to generate and modify the digital twin 28 and to determine the network impacts caused by planned changes to the physical environment 30. The models stored by the model repository 60 can be or can otherwise include various machine-learned models such as neural networks (e.g., deep neural networks) or other types of machine-learned models, including non-linear models and/or linear models. Neural networks can include feed-forward neural networks, recurrent neural networks (e.g., long short-term memory recurrent neural networks), convolutional neural networks or other forms of neural networks.

Some example machine-learned models can leverage an attention mechanism such as self-attention. For example, some example machine-learned models can include multi-headed self-attention models (e.g., transformer models). Additionally, or alternatively, in some other contexts, a model may refer to a portion of a model, or multiple models or portions of models. For example, a Generative Adversarial Network (GAN) can include an encoder model and decoder model during training, while the encoder model may be utilized exclusively during inference. The term “model” may refer to either, or both, of these models depending on the context in which the term is used.

One of the models stored by the model repository 60 can be, or otherwise include, a machine learning model 64. The machine learning model 64 can be trained to output data identifying a predicted impact of a planned change to the physical environment 30.

In some implementations, the computing system 10 may establish, for each respective physical environment of a plurality of physical environments, a ground truth radiation pattern impact caused by a change in the respective physical environments, and the machine learning model 64 may be trained based on the plurality of physical environments and the corresponding ground truth radiation pattern impacts. The modified digital twin 28 and location data indicating a location of the transceiver(s) 34 in the physical environment 30 may be input to the machine learning model 64. The machine learning model 64 may output data identifying a predicted impact of the planned change on the radiation pattern(s) of the transceiver(s) 34.

The model repository 60 may include a radiation simulator 66. The radiation simulator 66 can be trained to process the modified digital twin 28 and output data indicating an impact to the network caused by a planned change to the physical environment 30. More particularly, location data indicating a location of the transceiver(s) 34 in the physical environment 30 may be provided to the radiation simulator 66. The radiation simulator 66 may process the modified digital twin 28 to determine an impact to the radiation pattern(s) of the transceiver(s) 34 due to the planned change in the physical environment 30.

The radiation simulator 66 may further process the modified digital twin 28 with a plurality of different transceiver scenarios that respectively identify a set of one or more transceivers positioned at one or more locations in the modified digital twin 28. The radiation simulator 66 may determine a particular transceiver scenario of the plurality of transceiver scenarios based on a variety of metrics, such as, by way of non-limiting example, size and scope of the resulting radiation coverage.

The model repository 60 can include model information 68. The model information 68 can store and track various characteristics of the various machine-learned models 64-66 stored in the model repository 60. In particular, the model information 68 can include a timestamp for the last time a model was updated or trained, a version number, an identifier, local processing capabilities, estimated compute usage (e.g., X number of FLOPS to utilize for inference), processing latency (e.g., 15 seconds to generate a mesh representation), etc.

It should be noted that the model repository 60 can include any other type or manner of generative model that can generate an output suitable for use in generating a virtual representation of a physical environment. It should be further noted that the model repository 60 can also include any other type or manner of machine-learned model that can generate an output corresponding to a network impact caused by a physical change in a physical environment.

The machine-learned model handler 58 can utilize the model trainer 62 to train the machine-learned models 64-66. The model trainer 62 can include an iterative optimizer 70. The iterative optimizer 70 can train, or otherwise optimize, the machine-learned models 64-66 when the present event data 42 and/or the future event data 48 is received from, for instance, the computing device 14. Additionally, or alternatively, in some implementations, the iterative optimizer 70 can directly optimize model outputs from the machine-learned models 64-66.

The model trainer 62 can include a federated learning module 72. The federated learning module 72 can implement federated learning techniques to more efficiently optimize the machine-learned models 64-66. In this manner, updates to machine-learned models can be calculated and provided to a distributed network of computing devices in a federated manner.

The model trainer 62 can include loss functions 74. The loss functions 74 can include a loss function utilized to train each of the models included in the model repository 60 in a supervised manner. More specifically, the loss functions 74 can evaluate differences between the outputs of the models 64-66 and corresponding ground-truth outputs. For example, the machine learning model 64 can process the modified digital twin 28 to determine an impact to the radiation pattern(s) of the transceiver(s) 34. One of the loss functions 74 can evaluate a difference between the determined radiation pattern impact(s) and ground-truth radiation pattern impact(s). In some implementations, the loss functions 74 can include a loss function configured to train each of the machine-learned models 64-66 in an end-to-end fashion (e.g., training all of the models concurrently). The loss functions 74 can include various evaluation criteria selected to efficiently optimize the models included in the model repository 60.

The network impact module 20 can include a model output repository 76. The model output repository 76 can store outputs generated using the machine-learned models stored to the model repository 60. Specifically, the model output repository 76 can include a machine learning model output 78 that includes data output by the machine learning model 64. The model output repository 76 can include radiation simulator outputs 80-1-80-N (generally, radiation simulator outputs 80). The radiation simulator outputs 80 can include outputs from the radiation simulator 66.

The model output repository 76 can include model output information 82. Similar to the model information 68, the model output information 82 can store information descriptive of various characteristics of the model outputs 78-80.

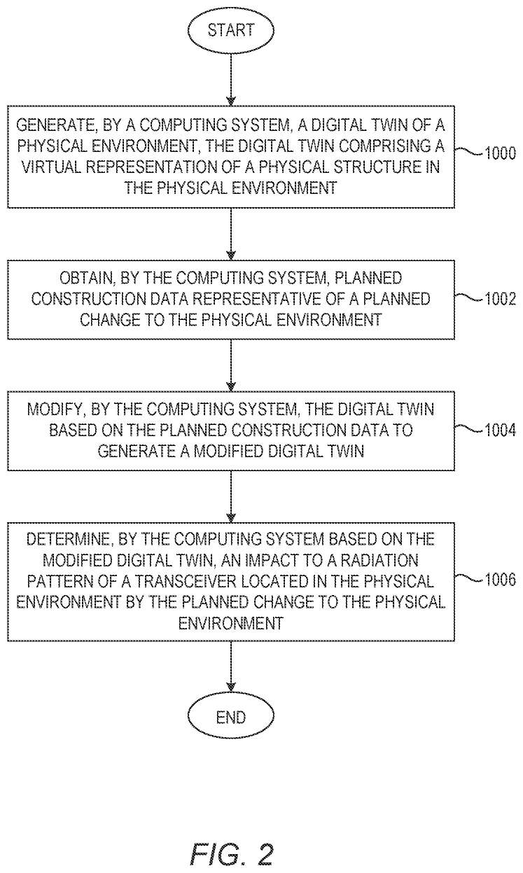

FIG. 2 is a flowchart of a method for determining a network impact according to one implementation of the present disclosure. FIG. 2 will be discussed in conjunction with FIG. 1. The computing system 10 generates a digital twin 28 of a physical environment 30; the digital twin 28 includes a virtual representation of a physical structure 32 in the physical environment 30 (FIG. 2, block 1000). The computing system 10 obtains planned construction data 50 representative of a planned change to the physical environment 30 (FIG. 2, block 1002). Subsequently, the computing system 10 modifies the digital twin 28 based on the planned construction data 50 to generate a modified digital twin 28 (FIG. 2, block 1004). Based on the modified digital twin 28, the computing system 10 determines an impact to a radiation pattern of a transceiver 34 located in the physical environment 30 that is caused by the planned change to the physical environment 30 (FIG. 2, block 1006).

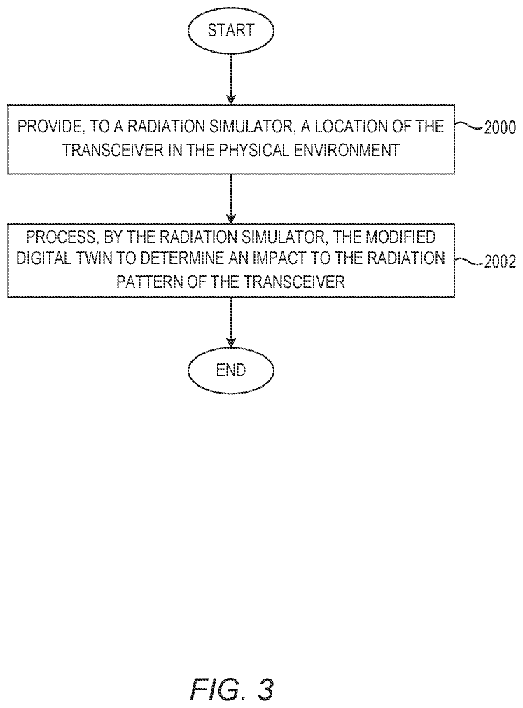

FIG. 3 is a flowchart of a method for determining an impact to a transceiver according to one implementation of the present disclosure. FIG. 3 will be discussed in conjunction with FIG. 1. The computing system 10 provides a location of the transceiver 34 in the physical environment 30 to a radiation simulator 66 (FIG. 3, block 2000). After providing the location of the transceiver 34 to the radiation simulator 66, the computing system 10 processes the modified digital twin 28 to determine an impact to the radiation pattern of the transceiver 34 (FIG. 3, block 2002).

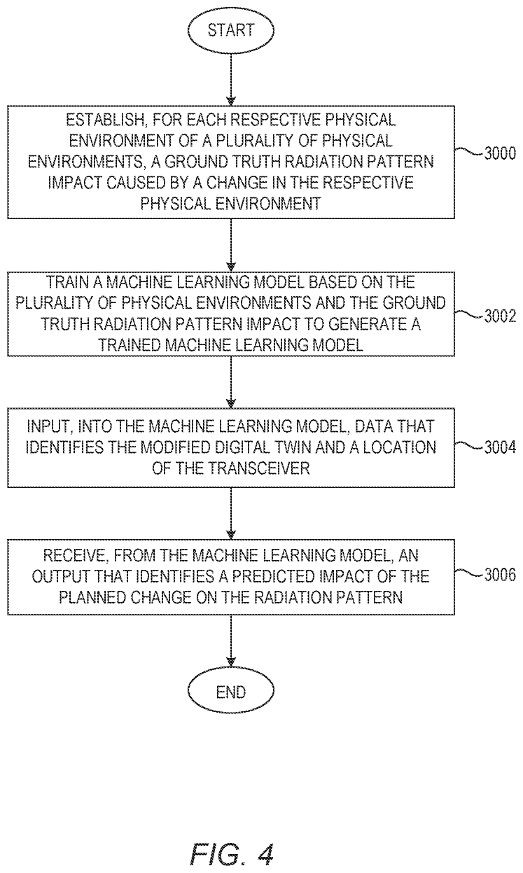

FIG. 4 is a flowchart of a method for predicting a network impact according to one implementation of the present disclosure. FIG. 4 will be discussed in conjunction with FIG. 1. The computing system 10 establishes, for each respective physical environment 30 of a plurality of physical environments, a ground truth radiation pattern impact caused by a change in the respective physical environment 30 (FIG. 4, block 3000). The computing system 10 trains a machine learning model 64 based on the plurality of physical environments and the ground truth radiation pattern impact, thereby generating a trained machine learning model 64 (FIG. 4, block 3002). Following training, the computing system 10 inputs, to the machine learning model 64, data that identifies the modified digital twin 28 and a location of the transceiver 34 (FIG. 4, block 3004). The computing system 10 receives an output from the machine learning model 64 that identifies a predicted impact on the radiation pattern that is caused by the planned change (FIG. 4, block 3006).

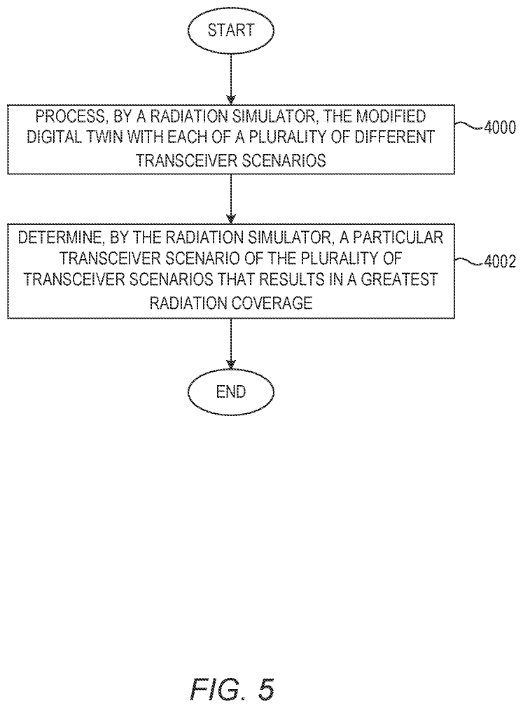

FIG. 5 is a flowchart of a method for determining a network configuration according to one implementation of the present disclosure. FIG. 5 will be discussed in conjunction with FIG. 1. The computing system 10 processes, by a radiation simulator 66, the modified digital twin 28 with each of a plurality of different transceiver scenarios, each of which identifying a set of one or more transceivers 34 positioned at one or more locations in the modified digital twin 28 (FIG. 5, block 4000). The computing system 10 determines, by the radiation simulator 66, a particular transceiver scenario of the plurality of transceiver scenarios that results in a greatest radiation coverage (FIG. 5, block 4002).

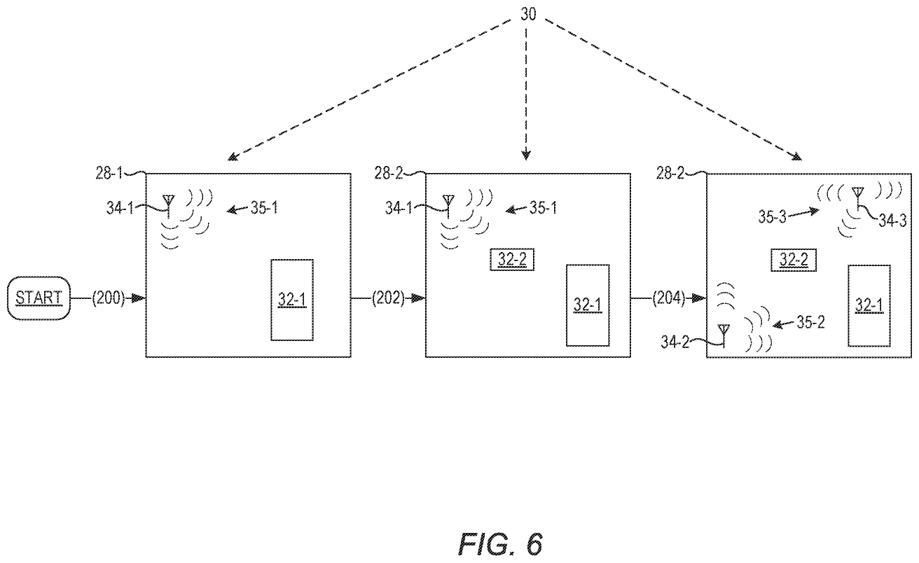

FIG. 6 is a diagram illustrating network capacity modifications based on planned structural changes according to one implementation of the present disclosure. FIG. 6 will be discussed in conjunction with FIG. 1.

At (200), as described above, the computing system 10 generates a digital twin 28-1 of a physical environment 30. The digital twin 28-1 includes a virtual representation of an existing physical structure 32-1 in the physical environment 30. The digital twin 28-1 may also include data corresponding to a location of an existing transceiver 34-1 in the physical environment 30, which includes a corresponding radiation pattern 35-1. While illustrated in two-dimensions for the purpose of illustration, the digital twin 28-1 may maintain three-dimensional data for the virtual representations of all physical structures.

At (202), after obtaining environment data (e.g., planned construction data 50) representative of a planned change to the physical environment 30, the computing system 10 modifies the digital twin 28-1 (based on the planned construction data 50) to generate a modified digital twin 28-2. Like the digital twin 28-1, the modified digital twin 28-2 includes a virtual representation of the existing physical structure 32-1, as well as data corresponding to the location of the existing transceiver 34-1. However, in some implementations, such as that depicted in FIG. 6, the planned construction data 50 includes the data 52 identifying a new physical structure 32-2 that is to be added to the physical environment 30. In such implementations, the modified digital twin 28-2 further includes a virtual representation of the new physical structure 32-2. In this manner, the computing system 10 may determine, based on the modified digital twin 28-2, one or more impacts to the radiation pattern 35-1 of the transceiver 34-1 caused by the addition of the new structure 32-2 in the physical environment 30.

In some implementations, although not depicted in FIG. 6, the modified digital twin 28-2 may include a virtual representation of a modification (e.g., expansion) to the existing structure 32-1 when the planned construction data 50 includes data 56 identifying the modification. Additionally and/or alternatively, in some implementations, although not depicted in FIG. 6, the modified digital twin 28-2 may not include the virtual representation of the existing structure 32-1 when the planned construction data 50 includes data 54 identifying that the existing structure 32-1 is to be removed from the physical environment 30.

At (206), after determining the one or more impacts to the radiation pattern 35-1 of the transceiver 34-1 caused by the addition of the new structure 32-2 in the physical environment 30, the computing system 10 processes the modified digital twin 28-2 with a plurality of transceiver scenarios that each identify a set of one or more transceivers positioned at one or more locations in the modified digital twin 28-2. Subsequently, the computing system 10 determines a particular transceiver scenario of the plurality of transceiver scenarios based on one or more desired criterion, such as, by way of non-limiting example, a greatest radiation coverage associated with the radiation patterns of the transceivers in the particular transceiver scenario, a lowest cost of network equipment sufficient to provide at least some wireless coverage in the physical environment, or the like. For example, as shown in the modified digital twin 28-2, the computing system 10 may determine, based on construction materials of the new physical structure 32-2, the height of the new physical structure 32-2, and other attributes of the new physical structure 32-2, that the new physical structure 32-2 that is to be added to the physical environment 30 will, from the perspective of the devices in the existing physical structure 32-1, block the radiation pattern 35-1 associated with the transceiver 34-1. Thus, the computing system 10 determines and suggests a mitigative action, such as the transceiver scenario resulting in the greatest radiation coverage. For instance, as shown, the computing system 10 may determine and suggest a transceiver scenario comprising transceiver 34-2 and transceiver 34-3 due to the resulting radiation coverage of radiation pattern 35-2 (associated with transceiver 34-2) and radiation pattern 35-3 (associated with transceiver 34-3). In this manner, the adverse effects to the radiation pattern 35-1 caused by the new physical structure 32-2 may be mitigated such that the wireless connectivity for the devices in the existing physical structure 32-1 is not adversely affected. In some implementations, the computing system 10 may provide multiple potential scenarios, indicating for each such scenario wireless coverage of the physical environment and identifying the network equipment necessary to implement the scenario. While not depicted in FIG. 6, the determination of the possible new locations of the transceiver may be limited to locations that are physically feasible and abide by local building standards.

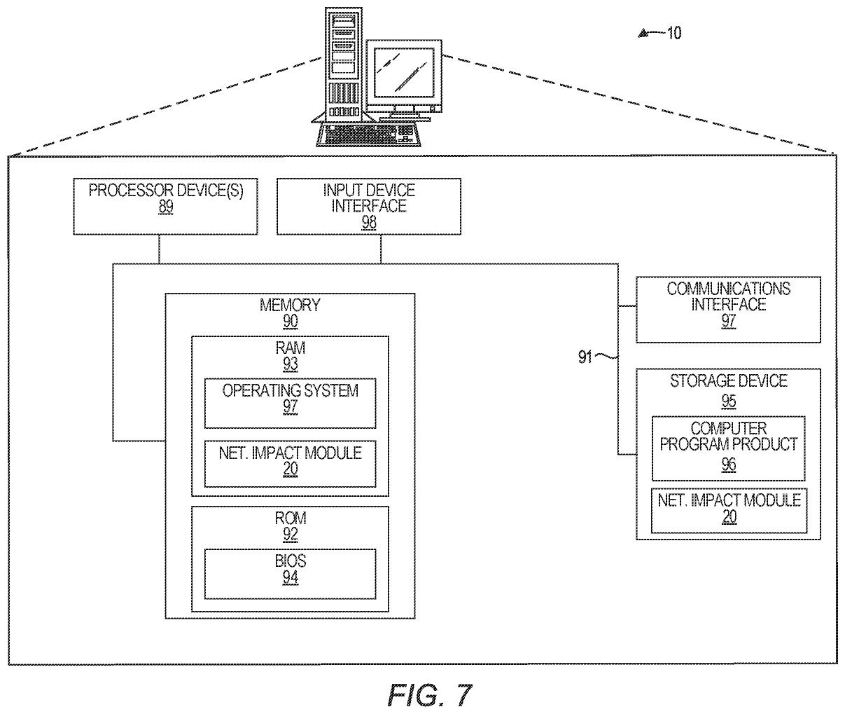

FIG. 7 is a block diagram of the computing system 10 suitable for implementing examples disclosed herein. The computing system 10 includes a processor device 89, a system memory 90, and a system bus 91. The system bus 91 provides an interface for system components including, but not limited to, the system memory 90 and the processor device 89. The processor device 89 can be any commercially available or proprietary processor.

The system bus 91 may be any of several types of bus structures that may further interconnect to a memory bus (with or without a memory controller), a peripheral bus, and/or a local bus using any of a variety of commercially available bus architectures. The system memory 90 may include non-volatile memory 92 (e.g., read-only memory (ROM), erasable programmable read-only memory (EPROM), electrically erasable programmable read-only memory (EEPROM), etc.), and volatile memory 93 (e.g., random-access memory (RAM)). A basic input/output system (BIOS) 94 may be stored in the non-volatile memory 93 and can include the basic routines that help to transfer information between elements within the computing system 10. The volatile memory 93 may also include a high-speed RAM, such as static RAM, for caching data.

The computing system 10 may further include or be coupled to a non-transitory computer-readable storage medium such as a storage device 95, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 95 and other drives associated with computer-readable media and computer-usable media may provide non-volatile storage of data, data structures, computer-executable instructions, and the like.

A number of modules can be stored in the storage device 95 and in the volatile memory 93, including an operating system and one or more program modules, which may implement the functionality described herein in whole or in part. All or a portion of the examples may be implemented as a computer program product 96 stored on a transitory or non-transitory computer-usable or computer-readable storage medium, such as the storage device 95, which includes complex programming instructions, such as complex computer-readable program code, to cause the processor device 89 to carry out the steps described herein. Thus, the computer-readable program code can comprise software instructions for implementing the functionality of the examples described herein when executed on the processor device 89. The processor device 89, in conjunction with the controller in the volatile memory 93, may serve as a controller, or control system, for the computing system 10 that is to implement the functionality described herein.

The computing system 10 may also include a number of communication interfaces, such as a communications interface 97, that are suitable for communicating with a network (or devices connected thereto) as appropriate or desired.

Because the network impact module 20 is a component of the computing system 10, functionality implemented by the network impact module 20 may be attributed to the computing system 10 generally. Moreover, in examples where the network impact module 20 comprises software instructions that program the processor device(s) 89 to carry out functionality discussed herein, functionality implemented by the network impact module 20 may be attributed herein to the processor device(s) 89.

An operator, such as a user, may also be able to enter one or more configuration commands through a keyboard (not illustrated), a pointing device such as a mouse (not illustrated), or a touch-sensitive surface such as a display device. Such input devices may be connected to the processor device(s) 89 through an input device interface 98 that is coupled to the system bus 91 but can be connected by other interfaces such as a parallel port, an Institute of Electrical and Electronic Engineers (IEEE) 1394 serial port, a Universal Serial Bus (USB) port, an IR interface, and the like. The computing system 10 may also include the communications interface/network connection (e.g., network connection or interface that enables a network connection) suitable for communicating with the network(s) 100 as appropriate or desired. The computing system 10 may also include a video port configured to interface with a display device, to provide information to the user.

Individuals will recognize improvements and modifications to the preferred examples of the disclosure. All such improvements and modifications are considered within the scope of the concepts disclosed herein and the claims that follow.

What is claimed is:

1. A method, comprising:
generating, by a computing system, a digital twin of a physical environment, the digital twin comprising a virtual representation of a physical structure in the physical environment;
obtaining, by the computing system, planned construction data representative of a planned change to the physical environment;
modifying, by the computing system, the digital twin based on the planned construction data to generate a modified digital twin; and
determining, by the computing system based on the modified digital twin, an impact to a radiation pattern of a transceiver located in the physical environment by the planned change to the physical environment.

2. The method of claim 1, further comprising:
accessing one or more images depicting the physical structure in the physical environment, and wherein generating the digital twin of the physical environment comprises generating, by the computing system, the digital twin of the physical environment based on the one or more images depicting the physical structure.

3. The method of claim 1, further comprising:
accessing construction data identifying a plurality of physical structures including the physical structure in the physical environment, and wherein generating the digital twin of the physical environment comprises generating, by the computing system, the digital twin of the physical environment based on the construction data.

4. The method of claim 3, wherein the construction data comprises a blueprint identifying the one or more physical structures.

5. The method of claim 1, wherein the planned construction data comprises a document that identifies physical attributes of the planned change to the physical environment.

6. The method of claim 1, wherein the planned construction data identifies a new structure that is to be added to the physical environment, and wherein modifying the digital twin based on the planned construction data to generate the modified digital twin comprises modifying the digital twin to include a virtual representation of the new structure.

7. The method of claim 1, wherein the planned construction data identifies an existing structure in the physical environment that is to be removed from the physical environment, and wherein modifying the digital twin based on the planned construction data to generate the modified digital twin comprises modifying the digital twin to remove a virtual representation of the existing structure.

8. The method of claim 1, wherein the planned construction data identifies an expansion to the physical structure in the physical environment, and wherein modifying the digital twin based on the planned construction data to generate the modified digital twin comprises modifying the virtual representation of the physical structure to include the expansion.

9. The method of claim 1, wherein determining the impact to the radiation pattern of the transceiver comprises:
providing, to a radiation simulator, a location of the transceiver in the physical environment; and
processing, by the radiation simulator, the modified digital twin to determine an impact to the radiation pattern of the transceiver.

10. The method of claim 1, wherein determining the impact to the radiation pattern of the transceiver comprises:
establishing, for each respective physical environment of a plurality of physical environments, a ground truth radiation pattern impact caused by a change in the respective physical environment;
training a machine learning model based on the plurality of physical environments and the ground truth radiation pattern impact to generate a trained machine learning model;
inputting, into the machine learning model, data that identifies the modified digital twin and a location of the transceiver; and
receiving, from the machine learning model, an output that identifies a predicted impact of the planned change on the radiation pattern.

11. The method of claim 10, wherein training the machine learning model based on the plurality of physical environments and the ground truth radiation pattern impact to generate the trained machine learning model further comprises training the machine learning model based on the plurality of physical environments, the ground truth radiation pattern impact, and one or more historical impacts based on one or more of actual measurements and data associated with feedback from a user to generate the trained machine learning model.

12. The method of claim 1, further comprising:
processing, by a radiation simulator, the modified digital twin with each of a plurality of different transceiver scenarios, each transceiver scenario identifying a set of one or more transceivers positioned at one or more locations in the modified digital twin; and
determining, by the radiation simulator, a particular transceiver scenario of the plurality of transceiver scenarios that results in a greatest radiation coverage.

13. The method of claim 1, wherein the modified digital twin is a three-dimensional digital twin, and wherein the modified digital twin identifies, for each virtual representation of a physical structure in the modified digital twin, an external construction material of the physical structure.

14. A computing system, comprising:
one or more computing devices operable to:
generate a digital twin of a physical environment, the digital twin comprising a virtual representation of a physical structure in the physical environment;
obtain planned construction data representative of a planned change to the physical environment;
modify the digital twin based on the planned construction data to generate a modified digital twin; and
determine, based on the modified digital twin, an impact to a radiation pattern of a transceiver located in the physical environment by the planned change to the physical environment.

15. The computing system of claim 14, wherein the one or more computing devices are operable to access one or more images depicting the physical structure in the physical environment and construction data identifying a plurality of physical structures including the physical structure in the physical environment, and wherein the digital twin is generated based on at least one of the one or more images depicting the physical structure or the construction data.

16. The computing system of claim 14, wherein the planned construction data identifies a new structure that is to be added to the physical environment, and wherein the one or more computing devices are operable to modify the digital twin to include a virtual representation of the new structure in the modified digital twin.

17. The computing system of claim 14, wherein the planned construction data identifies an existing structure in the physical environment that is to be removed from the physical environment, and wherein the one or more computing devices are operable to remove a virtual representation of the existing structure in the modified digital twin.

18. The computing system of claim 14, wherein, to determine the impact to the radiation pattern of the transceiver, the one or more computing devices are further operable to:
establish, for each respective physical environment of a plurality of physical environments, a ground truth radiation pattern impact caused by a change in the respective physical environment;
train a machine learning model of the computing system based on the plurality of physical environments and the ground truth radiation pattern impact to generate a trained machine learning model;
input, into the machine learning model, data that identifies the modified digital twin and a location of the transceiver; and
receive, from the machine learning model, an output that identifies a predicted impact of the planned change on the radiation pattern.

19. The computing system of claim 14, wherein the one or more computing devices are further operable to:
process, by a radiation simulator of the computing system, the modified digital twin with each of a plurality of different transceiver scenarios, each transceiver scenario identifying a set of one or more transceivers positioned at one or more locations in the modified digital twin; and
determine, by the radiation simulator, a particular transceiver scenario of the plurality of transceiver scenarios that results in a greatest radiation coverage.

20. A non-transitory computer-readable storage medium that includes executable instructions configured to cause one or more processor devices to:
generate a digital twin of a physical environment, the digital twin comprising a virtual representation of a physical structure in the physical environment;
obtain planned construction data representative of a planned change to the physical environment;
modify the digital twin based on the planned construction data to generate a modified digital twin; and
determine, based on the modified digital twin, an impact to a radiation pattern of a transceiver located in the physical environment by the planned change to the physical environment.
